(19) United States
(12) Patent Application Publication
(10) Pub. No.: US 2012/0218691 A1
(43) Pub. Date: Aug. 30, 2012

(54) ELECTRONIC DEVICE

(76) Inventors: Takashi Minemura, Tokyo (JP); Hiromichi Suzuki, Tokyo (JP); Yuji Nakajima, Tokyo (JP)

(21) Appl. No.: 13/300,361

(22) Filed: Nov. 18, 2011

(30) Foreign Application Priority Data
Feb. 28, 2011 (JP) 2011-043136

(51) Int. Cl. H05K 5/02

(52) U.S. Cl. 361/679.01

(57) ABSTRACT

According to one embodiment, an electronic device includes a first housing, a second housing, a connection portion, and a resistance mechanism. The first housing includes a first edge and a first display screen. The second housing includes a second edge extending along the first edge and a second display screen capable of facing the first display screen. The connection portion includes a contact portion that is in contact with a plane when one of the housings is placed on the plane and the other is raised. The connection portion is connected to the first edge to be rotatable about a first rotation axis and the second edge to be rotatable about a second rotation axis parallel to the first rotation axis. The resistance mechanism applies different resistance to the rotation of the first housing and the connection portion and to the rotation of the second housing and the connection portion.

### CROSS-REFERENCE TO RELATED APPLICATIONS

This application is based upon and claims the benefit of priority from Japanese Patent Application No. 2011-043136, filed Feb. 28, 2011, the entire contents of which are incorporated herein by reference.

### FIELD

Embodiments described herein relate generally to an electronic device.

### BACKGROUND

There have been known electronic devices having two housings that are rotatably connected via two parallel rotation axes such that the housings can move between their open and closed positions. Thus, such an electronic device switches between open and closed states.

This type of electronic device may be awkward to use depending on the orientation (angle, open position) of the two housings when opened from the closed state.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of an electronic device in open state according to an embodiment;

FIG. 2 is an exemplary side view of the electronic device in the open state in the embodiment;

FIG. 3 is an exemplary plan view of the electronic device in the open state in the embodiment;

FIG. 4 is an exemplary side view of the electronic device in the open state in the embodiment;

FIG. 5 is an exemplary side view of the electronic device in closed state in the embodiment;

FIG. 6 is an exemplary plan view of the electronic device in the closed state in the embodiment;

FIGS. 7 and 8 are exemplary perspective views of the electronic device in the open state viewed at different angles in the embodiment;

FIG. 9 is an exemplary schematic diagram of a control circuit of the electronic device in the embodiment;

FIG. 10 is an exemplary front view of a hinge mechanism of the electronic device in the open state in the embodiment;

FIG. 11 is an exemplary side view of the hinge mechanism of the electronic device in the open state in the embodiment;

FIG. 12 is an exemplary side view of the hinge mechanism of the electronic device in placed mode in the embodiment;

FIG. 13 is an exemplary side view of the electronic device in the placed mode corresponding to FIG. 12 in the embodiment;

FIG. 14 is an exemplary cross-sectional view taken along line XIV-XIV of FIG. 6 in the embodiment;

FIG. 15 is an exemplary side view of the hinge mechanism of the electronic device in the closed state in the embodiment;

FIG. 16 is an exemplary perspective view of an electronic device according to a modification of the embodiment;

FIG. 17 is an exemplary perspective view of an electronic device according to another modification of the embodiment; and

FIG. 18 is an exemplary perspective view of an electronic device according to still another modification of the embodiment.

### DETAILED DESCRIPTION

In general, according to one embodiment, an electronic device comprises a first housing, a second housing, a connection portion, and a resistance mechanism. The first housing comprises a first edge and a first display screen. The second housing comprises a second edge extending along the first edge and a second display screen capable of facing the first display screen. The connection portion comprises a contact portion that is in contact with a plane when either the first housing or the second housing is placed on the plane and either the second housing or the first housing is raised, the connection portion is configured to be connected to the first edge to be rotatable about a first rotation axis and connected to the second edge to be rotatable about a second rotation axis parallel to the first rotation axis. The resistance mechanism is configured to apply different resistance to the rotation of the first housing and the connection portion and to the rotation of the second housing and the connection portion.

In exemplary embodiments and modifications thereof described below, like elements are designated by like reference numerals, and their description is not repeated.

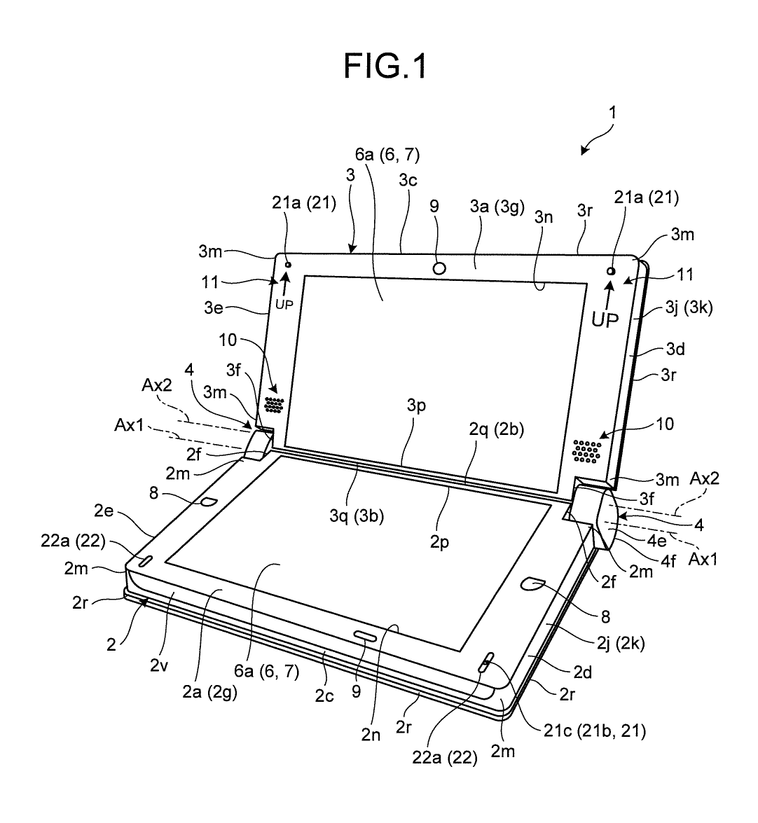

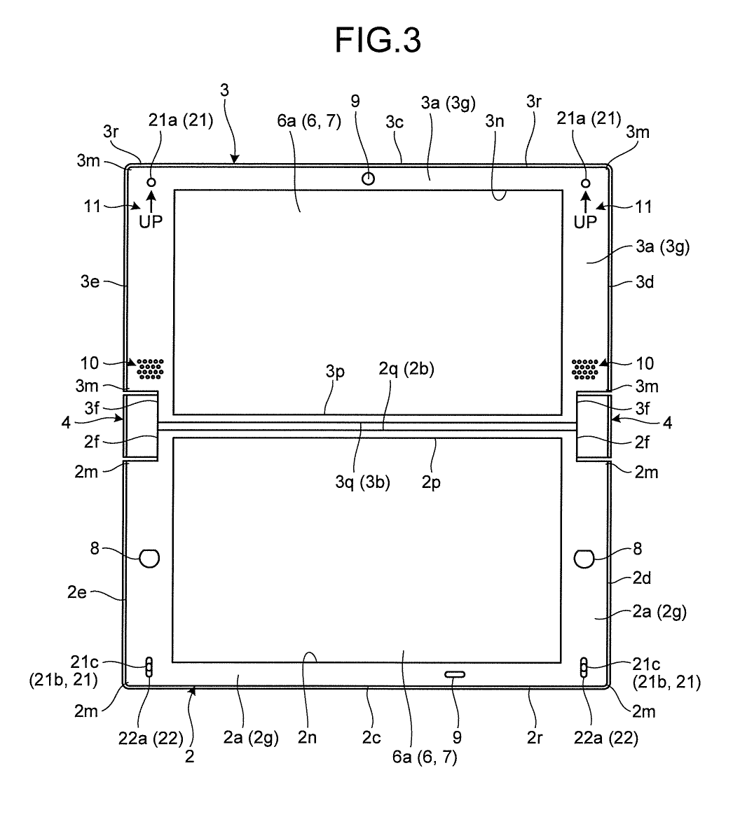

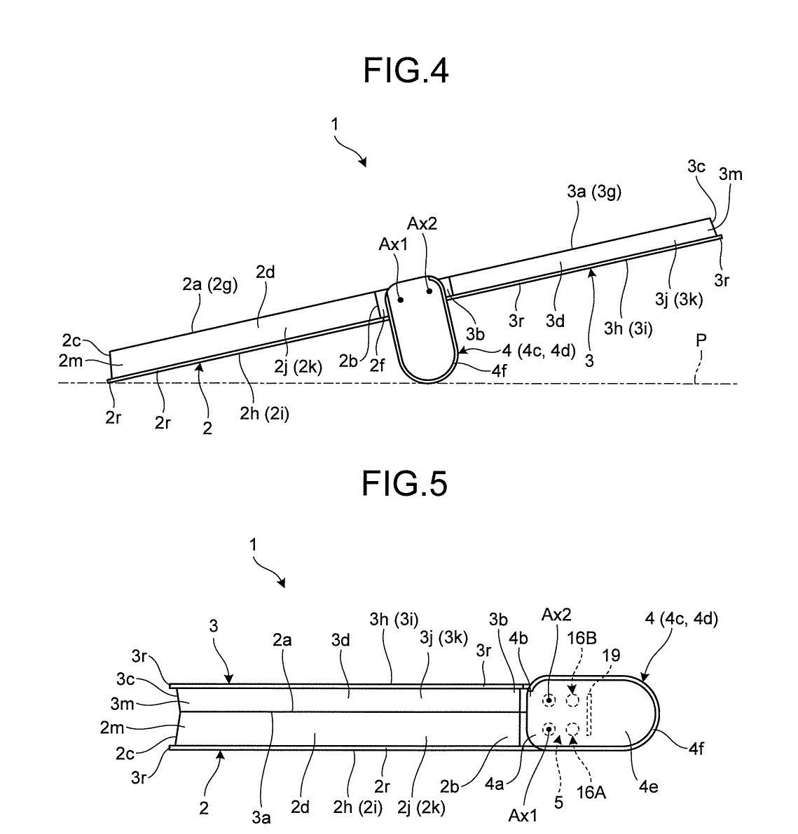

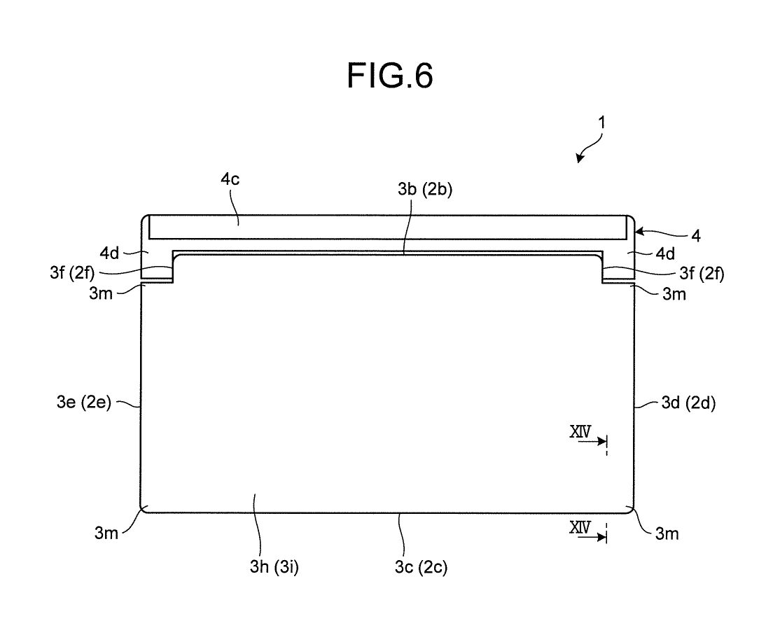

As illustrated in FIG. 1, an electronic device 1 of an embodiment is, for example, a notebook personal computer (PC). The electronic device 1 comprises a flat rectangular first housing 2 and a flat rectangular second housing 3. The first housing 2 and the second housing 3 are connected by a connection portion 4 to be relatively rotatable (movable) between their open position illustrated in FIGS. 1 to 4 and their closed position illustrated in FIGS. 5 and 6. As illustrated in FIGS. 3 and 4, in the open position where the first housing 2 and the second housing 3 are opened at the maximum angle (180°), a surface 2a of the first housing 2 and a surface 3a of the second housing 3 lie substantially in a plane. On the other hand, in the closed position, the surface 2a of the first housing 2 closely faces the surface 3a of the second housing 3.

In the embodiment, regardless of the angle at which the first housing 2 and the second housing 3 are positioned, i.e., at various angles in the open and closed positions as illustrated in FIGS. 1 to 6, an edge 2b (side) as part of the periphery of the first housing 2 and an edge 3b (side) as part of the periphery of the second housing 3 extend substantially in parallel close to each other. That is, in the embodiment, the first housing 2 and the second housing 3 are connected to be relatively rotatable with the edges 2b and 3b as bases and opposite edges 2c and 3c as distal edges. In the embodiment, the edge 2b is an example of a first edge, while the edge 3b is an example of a second edge.

The connection portion 4 is rotatably connected to the base of the first housing 2 and that of the second housing 3, i.e., both the edges 2b and 3b. More specifically, as illustrated in FIGS. 1 and 5, an edge 4a of the connection portion 4 and the edge 2b of the first housing 2 are connected to be relatively rotatable about a first rotation axis Ax1. Meanwhile, an edge 4b of the connection portion 4 on the opposite side of the edge 4a and the edge 3b of the second housing 3 are connected to be relatively rotatable about a second rotation axis Ax2. The first rotation axis Ax1 and the second rotation axis Ax2 extend in parallel along with each other. The connection portion 4 comprises a housing 4e that houses hinge mechanisms 5. In other words, the housing 4e is an example of a cover of the hinge mechanisms 5.

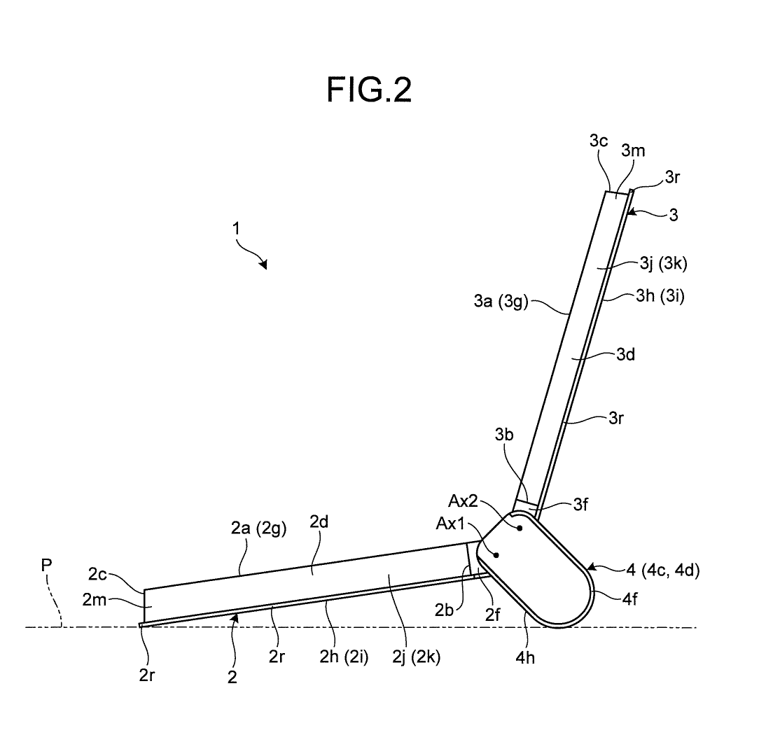

In the embodiment, as illustrated in FIG. 6, the connection portion 4 comprises a base 4c and protrusions 4d. The base 4c faces the edge 2b of the first housing 2 and the edge 3b of the second housing 3 with a space therebetween and extends along the edges 2b and 3b. Besides, as illustrated in FIG. 2, the base 4c extends in a direction away from the edges 2b and 3b. As illustrated in FIG. 6, the protrusions 4d extend along edges 2d and 2e (sides) of the first housing 2 and edges 3d and 3e (sides) of the second housing 3, respectively, from the longitudinal both ends of the base 4c toward the edge 2c of the first housing 2 and the edge 3c of the second housing 3. The edges 2d and 2e of the first housing 2 and the edges 3d and 3e of the second housing 3 are provided with notch-like recesses 2f and 3f (notches) corresponding to the two protrusions 4d, respectively. The protrusions 4d are housed in the recesses 2f and 3f, respectively. In the embodiment, the two protrusions 4d houses the independent hinge mechanisms 5, respectively. The electronic device 1 of the embodiment is structured such that the required rigidity of the connection portion 4 and the edges 2b and 3b is ensured, and the first rotation axis Ax1 and the second rotation axis Ax2 in one of the two hinge mechanisms 5 (see FIG. 5) substantially match those in the other, respectively.

As illustrated in FIGS. 1 and 3, the first housing 2 has, as walls, a front wall 2g forming the surface 2a as the front surface, a back wall 2i forming a surface 2h as the back surface (see FIG. 5), and a circumferential wall 2k (side wall) forming a surface 2j as the side surface. The front wall 2g is provided with a rectangular opening 2n. The first housing 2 houses a display panel 6 as a display module (display device). Examples of the display panel 6 include a liquid crystal display (LCD) panel and an organic electroluminescent display (OELD) panel. The display panel 6 comprises a display screen 6a as part of the front surface which is exposed from the opening 2n. The first housing 2 has four corners 2m. Two of the four corners 2m on the side of the edge 2b as the base are provided with the recesses 2f that house the protrusions 4d of the connection portion 4, respectively, as described above.

As illustrated in FIGS. 1 and 3, the second housing 3 has, as walls, a front wall 3g forming the surface 3a as the front surface, a back wall 3i forming a surface 3h as the back surface (see FIG. 5), and a circumferential wall 3k (side wall) forming a surface 3j as the side surface. The front wall 3g is provided with a rectangular opening 3n. The second housing 3 houses a display panel 6 as a display module (display device). Examples of the display panel 6 include a liquid crystal display (LCD) panel and an organic electroluminescent display (OELD) panel. The display panel 6 comprises a display screen 6a as part of the front surface which is exposed from the opening 3n. The second housing 3 has four corners 3m. Two of the four corners 3m on the side of the edge 3b as the base are provided with the recesses 3f that house the protrusions 4d of the connection portion 4, respectively, as described above.

As illustrated in FIGS. 1 and 3, in the embodiment, the opening 2n of the first housing 2 extends to an area (protruding portion) between the recesses 2f of the edge 2b. An edge 2p of the opening 2n on the edge 2b side is located near the edge 2b (an edge 2q as part of the periphery of the surface 2a). Meanwhile, the opening 3n of the second housing 3 extends to an area (protruding portion) between the recesses 3f of the edge 3b. An edge 3p of the opening 3n on the edge 3b side is located near the edge 3b (an edge 3q as part of the periphery of the surface 3a). That is, in the embodiment, the openings 2n and 3n are located close to each other. Besides, the first housing 2 and the second housing 3 are rotated about a plurality of rotation axes (in the embodiment, the first rotation axis Ax1 and the second rotation axis Ax2). Accordingly, as illustrated in FIGS. 1 and 3, in the open position, a space (undisplayable area, non-display area, non-display portion, non-display width) between the display screen 6a of the first housing 2 and the display screen 6a of the second housing 3 can be narrowed (reduced). With this, when a continuous video image (a still image, a moving image, etc.) is displayed on the two display screens 6a, discontinuity or distortion can be reduced in the image on the display screens 6a.

The display panels 6 are each provided with a thin touch panel 7 as an input operation module on the front surface (upper surface). The touch panel 7 senses a finger, a stylus, or the like touching or being close to the front surface (or a change in the state). The touch panel 7 is formed transparent (having translucency). Accordingly, the light of video displayed on the display screen 6a is emitted to the front surface side through the touch panel 7. The user (viewer) recognizes the light as the video. In the embodiment, the touch panel 7 is an example of a first panel or a second panel.

On the surfaces 2a and 3a that are exposed when the electronic device 1 is open state, there is provided an operation module 8 (input module) including, for example, buttons (power button, click button, etc.), a pointing device used to move a selected region such as a cursor on the display screen 6a around the openings 2n and 3n. Further, on the surfaces 2a and 3a, there may be provided an input module 9 such as, for example, a camera as an image capturing module, a microphone as an audio input module, and the like, or an output module 10 such as, for example, a speaker as an audio output module, a lamp and a light-emitting diode (LED) as display output module, and the like.

As described above, in the embodiment, the touch panel 7 is arranged on the front surface of each of the display panels 6. Accordingly, almost all areas of the display screens 6a in the openings 2n and 3n can be an input operation module. As illustrated in FIGS. 1 and 2, the electronic device 1 of the embodiment can be used in the state where one of the first housing 2 and the second housing 3 (for example, the first housing 2) is placed on a plane P (placement surface, see FIG. 2) and the other (for example, the second housing 3) is raised from the first housing 2 (one of first placed modes). In this case, an image (not illustrated) representing a text input module (for example, an image of a keyboard, a frame surrounding letters, elements corresponding to letters, etc.) is displayed automatically or manually on the display screen 6a of the one housing (placed housing, the first housing 2). If the resistance to the rotation of the first housing 2 on the connection portion 4 is larger than the resistance to the rotation of the second housing 3 on the connection portion 4, a text input image (image for input operation) such as an image of a keyboard may be displayed preferentially on the display screen 6a of the first housing 2. The touch panel 7 receives input from the outside through the text input image (image for input operation).

There are two types of such placed modes that one of the first housing 2 and the second housing 3 is placed on the plane P as follows: (1) mode where the first housing 2 is a placed part while the second housing 3 is a raised part (one of the first placed modes, see FIGS. 1 and 2); and (2) mode where the second housing 3 is the placed part while the first housing 2 is the raised part (the other of the first placed modes, not illustrated). The electronic device 1 is configured to be used in both the modes (orientations). However, if one of the modes (for example, the mode (1)) is preferred as placed mode for some reason, a display element 11 (for example, design, image, symbol, character, etc.) may be provided to the surface 2a or 3a to indicate the use mode of the electronic device 1, i.e., to make the user conscious of the orientation. The display element 11 may be a logo, a product name, a manufacture name, or the like. Further, as illustrated in FIG. 4, the electronic device 1 can be used in the following mode: (3) both the first housing 2 and the second housing 3 are placed on the plane P (placement surface) without raising one of them that is not the placed part (second placed mode).

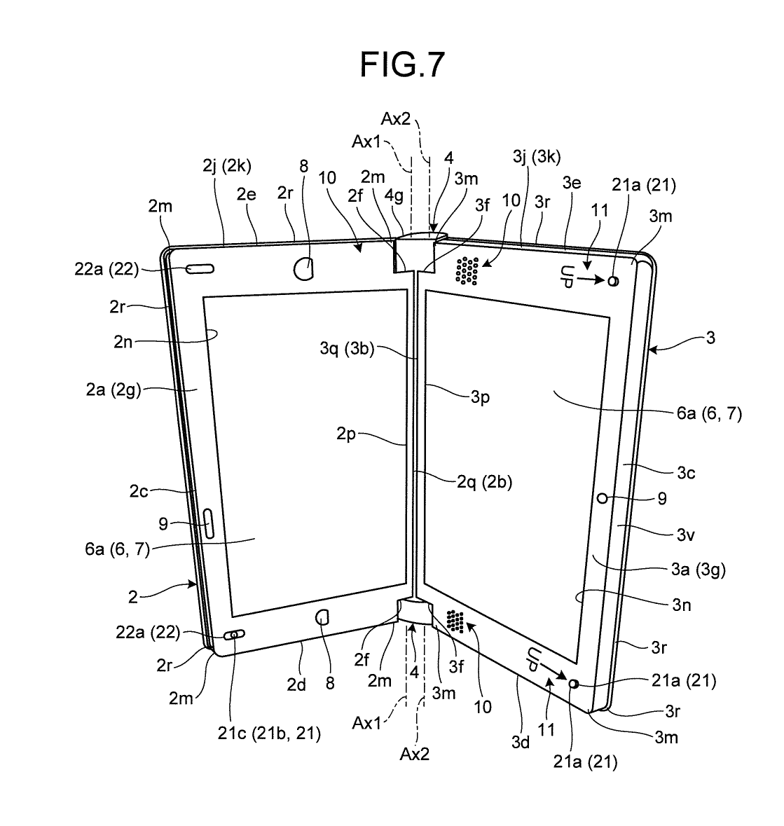

The electronic device 1 of the embodiment can also be used in the following modes: (4) the edge 2d of the first housing 2 and the edge 3d of the second housing 3 are placed on the plane P (placement surface) (one of the third placed modes, see FIG. 7); and (5) the edge 2e of the first housing 2 and the edge 3e of the second housing 3 are placed on the plane P (placement surface) (the other of the third placed modes, not illustrated).

In the first embodiment, the connection portion 4 comprises a contact portion 4f (see FIGS. 1 and 2) that extends along the edges 2d and 3d in a direction away from the edges 2b and 3b. The contact portion 4f comes in contact with the plane P (placement surface) together with the edge 2d of the first housing 2 and the edge 3d of the second housing 3 when the electronic device 1 is used in the mode (4). That is, the contact portion 4f is located in the same plane as the edges 2d and 3d. The connection portion 4 further comprises a contact portion 4g (see FIG. 7) on the opposite side of the contact portion 4f that extends along the edges 2e and 3e in a direction away from the edges 2b and 3b. The contact portion 4g comes in contact with the plane P (placement surface) when the electronic device 1 is used in the mode (5). That is, similar to the contact portion 4f, the contact portion 4g is located in the same plane as the edges 2e and 3e. In this manner, the connection portion 4 of the embodiment extends to the back surface side of the display screen 6a. With this, the base portions extend along the plane P (placement surface) in three directions from the edges 2b and 3b. Thus, in the third placed modes (4) and (5) described above, the electronic device 1 can be placed more securely compared to the case of without the connection portion 4. With the connection portion 4, when used in the third placed modes, the electronic device 1 is less likely to fall over backward.

Further, as illustrated in FIG. 5, the edges 2d and 2e on the both sides of the first housing 2 in the width direction are provided with a flared portion 2r that extends outward from the periphery of the back wall 2i as a wall located opposite the display screen 6a. Similarly, the edges 3d and 3e on the both sides of the second housing 3 in the width direction are provided with a flared portion 3r that extends outward from the periphery of the back wall 3i as a wall located opposite the display screen 6a. In the third placed modes (4) and (5) (see FIG. 7), the flared portions 2r and 3r come in contact with the plane P (placement surface) together with the contact portions 4f and 4g. Accordingly, compared to the case where the flared portions 2r and 3r are not provided, the display panels 6 are less likely to be subjected to a shock when the electronic device 1 is place on a desk or the like. This improves the protection of the display panels 6. Besides, the display panels 6 can be more separated from the surface of the desk or the like by the flared portions 2r and 3r. Thus, even if liquid such as water is spilled on the plane P such as the surface of a desk, the display panels 6 are less likely to be affected by the liquid. The flared portions 2r and 3r are also provided to the edges 2c and 3c, respectively. With this, the user can easily open the first housing 2 and the second housing 3 from the closed position by putting his/her fingers on the flared portions 2r and 3r. In the embodiment, the flared portion 2r is provided to the three edges 2c, 2d, and 2e except the edge 2b of the first housing 2, while the flared portion 3r is provided to the three edges 3c, 3d, and 3e except the edge 3b of the second housing 3.

According to the embodiment, in a mode (first held mode) where the electronic device 1 is held such that the first housing 2 and the second housing 3 are aligned horizontally (left and right) as illustrated in FIG. 7, the user can use the connection portion 4 extending (protruding) backward from the edges 2b and 3b as a handle (held portion). Thus, the user can hold the electronic device 1 by his/her thumb and fingers or the like without touching the display screens 6a. The connection portion 4 helps the user hold the electronic device 1 by hand.

Besides, according to the embodiment, in a mode (second held mode) where the electronic device 1 is held such that the first housing 2 and the second housing 3 are aligned vertically (up and down) as illustrated in FIG. 3, the user can use any of the edges 2c, 2d, and 2e of the first housing 2 and the edges 3c, 3d, and 3e of the second housing 3 as a handle (held portion). At the edges 2c, 2d, 2e, 3c, 3d, and 3e, the periphery of the display panels 6 (the openings 2n and 3n) is separated from the periphery of the corresponding surfaces 2a and 3a. Thus, when the user holds any of the edges 2c, 2d, 2e, 3c, 3d, and 3e of the electronic device 1 by hand or the like, his/her thumb or the like is less likely to touch the display screens 6a.

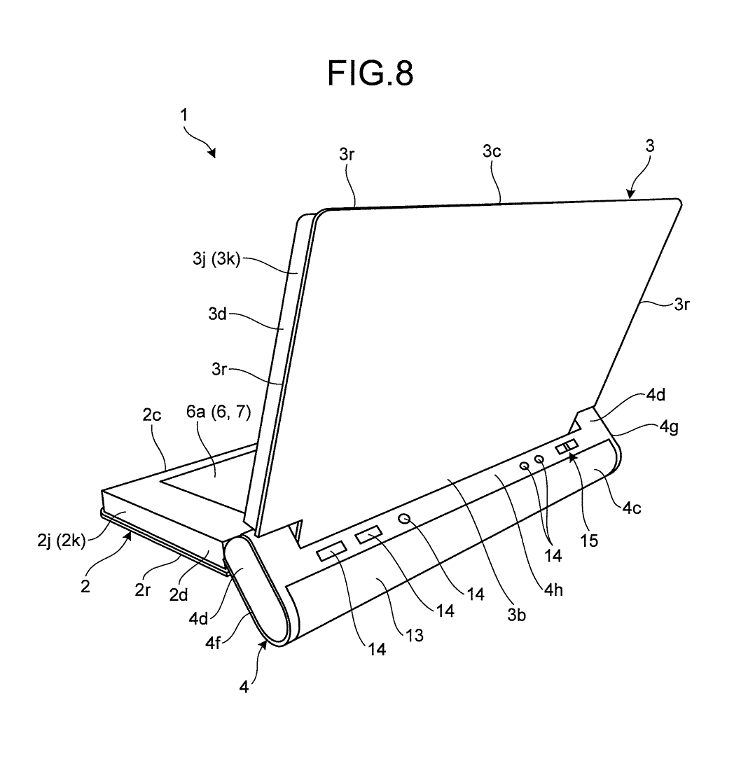

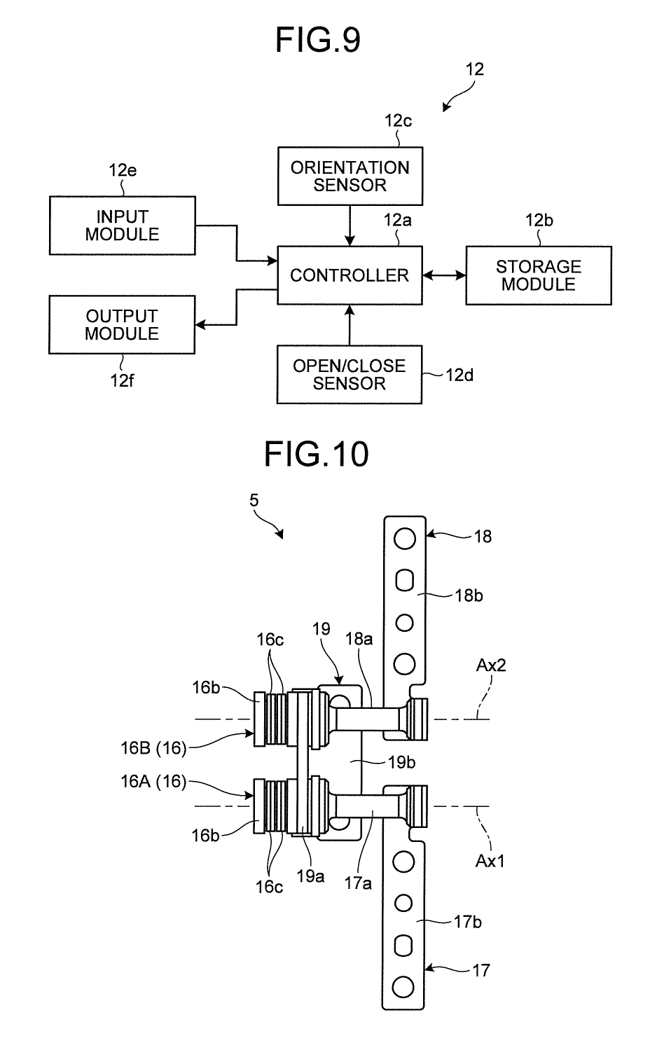

In the embodiment, as illustrated in FIG. 8, the connection portion 4 may be provided with, on its outer surface 4h, a connector 14 for connection of a component such as a digital interface connector to which is inserted an external connector and an operation module 15 (input operation module) including an operation button (a press button), a switch, and the like. Examples of the digital interface connector include an alternating current (AC) adapter connector, a universal serial bus (USB) connector, a card connector, and the like. Preferably, the connector 14 and the operation module 15 are located on part of the outer surface 4h which is exposed or likely to be exposed in each mode (especially, the placed modes (1), (2), etc.).

The connection portion 4 may house (hold, contain) a battery 13 as a power source to make the electronic device 1 operate. The battery 13 can be configured to be removably attached to the connection portion 4. Since the connection portion 4 of the embodiment extends along the edges 2b and 3b, the relatively long and large-capacity battery 13 can be set therein.

At least one of the first housing 2 and the second housing 3 houses a circuit board, an electronic component, and the like (not illustrated) and there is formed a control circuit 12 as illustrated in FIG. 12. The control circuit 12 of the embodiment comprises a controller 12a, a storage module 12b, an orientation sensor 12c, an open/close sensor 12d, an input module 12e, and an output module 12f. The controller 12a comprises, for example, a central processing unit (CPU), and controls the output module 12f based on an orientation detection result obtained by the orientation sensor 12c and input through the input module 12e. The orientation sensor 12c may be, for example, an accelerometer or a gyroscope to measure the direction of the gravitational force and detects the orientation of the electronic device 1. The open/close sensor 12d may be, for example, a contact sensor, a pressure sensor, a contactless sensor (a magnetic sensor). The open/close sensor detects the open/closed position, open/closed state, relative position, angle, and the like of the first housing 2 and the second housing 3. The input module 12e is formed as, for example, the touch panel 7, the operation module 8, the input module 9 as described above, or the like. The output module 12f is formed as, for example, the display panel 6, the output module 10 as described above, or the like. The controller 12a is an example of a display controller. The input module 12e (the operation module 8) is an example of an input operation module. The control circuit 12 further comprises a controller (not illustrated).

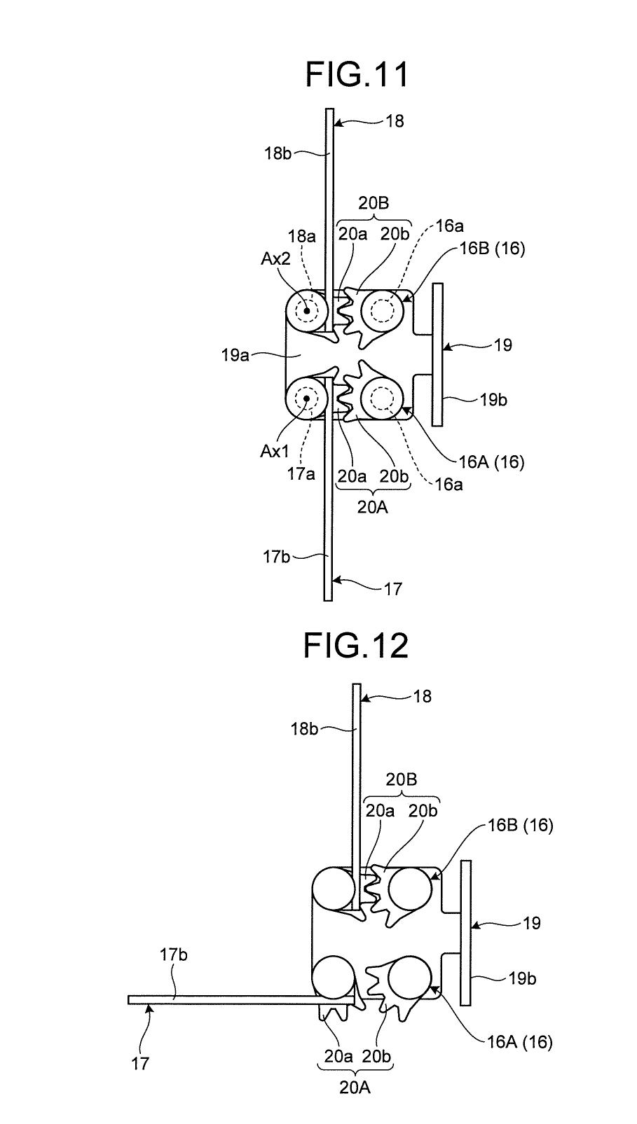

As illustrated in FIGS. 10 and 11, the hinge mechanism 5 comprises a first portion 17, a second portion 18, and a third portion 19. The first portion 17 is connected to the first housing 2. The second portion 18 is connected to the second housing 3. The third portion 19 is rotatably connected to both the first portion 17 and the second portion 18 and supported by the connection portion 4. The first portion 17 and the third portion 19 are connected to be rotatable about the first rotation axis Ax1. The second portion 18 and the third portion 19 are connected to be rotatable about the second rotation axis Ax2. The first rotation axis Ax1 and the second rotation axis Ax2 extend in parallel. Incidentally, the third portion 19 is an example of a connection portion.

In the hinge mechanism 5, for example, the third portion 19 comprises a base 19a as a plate-like wall and a piece 19b as a wall rising from an end of the base 19a. The first portion 17 comprises a shaft 17a extending from the base 19a and an arm-like piece 17b attached to the shaft 17a. The second portion 18 comprises a shaft 18a extending from the base 19a and an arm-like piece 18b attached to the shaft 18a. The shafts 17a and 18a are rotatably supported by the base 19a. In the embodiment, the central axis of the shaft 17a corresponds to the first rotation axis Ax1, while the central axis of the shaft 18a corresponds to the second rotation axis Ax2.

In the embodiment, there are provided resistance mechanisms 16A and 16B near the hinge mechanism 5. The resistance mechanism 16A applies resistance (torque) to the rotation of the first housing 2 and the connection portion 4. The resistance mechanism 16B applies resistance (torque) to the rotation of the second housing 3 and the connection portion 4. The resistance mechanisms 16A and 16B constitutes a resistance mechanism 16 that applies resistance to the movement (relative movement) of the first housing 2 and the second housing 3. The resistance mechanisms 16A and 16B cause friction resistance (slide resistance) to act on two elements that relatively rotate (for example, the first portion 17 and the third portion 19, the first portion 17 and the housing 4e of the connection portion 4, the second portion 18 and the third portion 19, the second portion 18 and the housing 4e of the connection portion 4, etc.) by resistance elements 16c (for example, disc springs, coil springs, etc.). The resistivity of the resistance mechanism 16 is set appropriate so that, at various (arbitrary) angles between the first housing 2 and the second housing 3 (in a predetermined angle range), the orientation (angle) is not changed by the act of gravity (maintained) but is variable by an appropriate external force from a finger or the like.

For example, in the embodiment, the resistance mechanism 16A applies resistance to the movement (relative movement) of the first portion 17 and the third portion 19. Meanwhile, the resistance mechanism 16B applies resistance to the movement (relative movement) of the second portion 18 and the third portion 19. The resistance mechanisms 16A and 16B each comprise a shaft 16a, a disc-like cap 16b, and a plurality of disc springs 16c as resistance elements (elastic members). The shaft 16a extends from the base 19a. The cap 16b is fixed to the shaft 16a at a position distant from the base 19a. The disc springs 16c are sandwiched between the cap 16b and the base 19a as being resiliently compressed. The shaft 16a is rotatably supported by the base 19a. The central axis of the shaft 16a is set to be in parallel to the first rotation axis Ax1 and the second rotation axis Ax2. The disc springs 16c are each formed in a ring-like shape having an opening (for example, a hole, a notch, etc., not illustrated) in the center, and the shaft 16a passes through the opening. The rotation of the piece 17b of the first portion 17 and the shaft 17a is transmitted to the shaft 16a and the cap 16b of the resistance mechanism 16A via a transmission mechanism 20A comprising gears 20a and 20b. Similarly, the rotation of the piece 18b of the second portion 18 and the shaft 18a is transmitted to the shaft 16a and the cap 16b of the resistance mechanism 16B via a transmission mechanism 20B comprising gears 20a and 20b. The gears 20a are fixed to the shafts 17a and 18a or the pieces 17b and 18b, respectively. Meanwhile, the gears 20b are each fixed to the shaft 16a or the cap 16b.

With this structure, the rotation (relative rotation) of the first portion 17 with respect to the third portion 19 is transmitted to the cap 16b of the resistance mechanism 16A by the transmission mechanism 20A, and thereby the cap 16b rotates. At this time, resilient repulsive force along the axis direction of the shaft 16a in the disc springs 16c causes rotation resistance (slide resistance, friction resistance) between the third portion 19 and the cap 16b and also causes rotation resistance (slide resistance, friction resistance) between the third portion 19 and the first portion 17. Similarly, the rotation (relative rotation) of the second portion 18 with respect to the third portion 19 is transmitted to the cap 16b of the resistance mechanism 16B by the transmission mechanism 20B, and thereby the cap 16b rotates. At this time, resilient repulsive force along the axis direction of the shaft 16a in the disc springs 16c causes rotation resistance (slide resistance, friction resistance) between the third portion 19 and the cap 16b and also causes rotation resistance (slide resistance, friction resistance) between the third portion 19 and the second portion 18. That is, in the embodiment, the resistance of the first portion 17 to the third portion 19 is set by the resistance mechanism 16A, and the resistance of the second portion 18 to the third portion 19 can be set by the resistance mechanism 16B other than the resistance mechanism 16A.

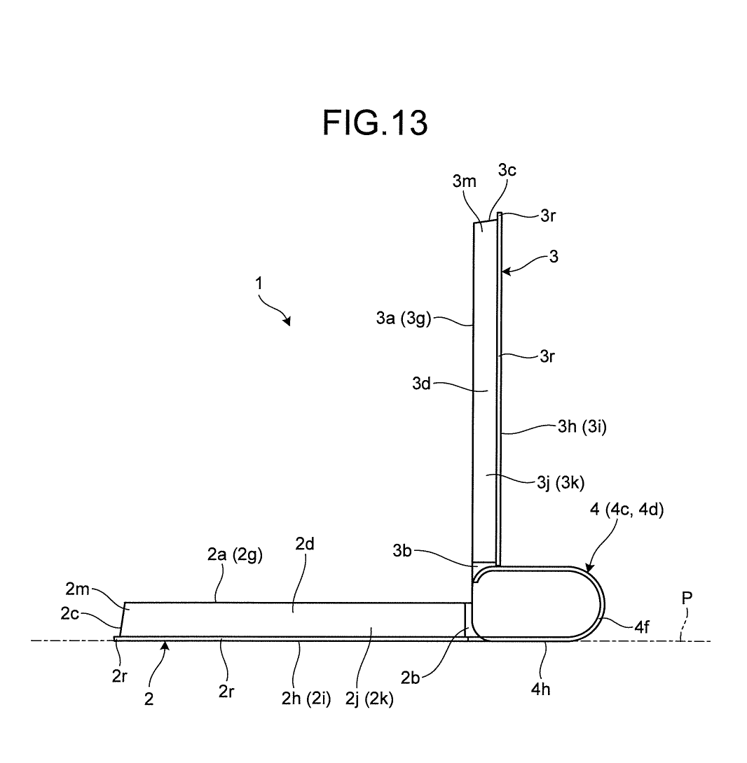

Accordingly, in the embodiment, by differentiating the specifications (the number of the disc springs 16c, the resilience, etc.) of the resistance elements between the resistance mechanisms 16A and 16B, it is possible to relatively easily differentiate resistance to the rotation of the first housing 2 and the connection portion 4 from resistance to the rotation of the second housing 3 and the connection portion 4. Thus, it is possible to relatively easily achieve a mode (state) where, with respect to the connection portion 4, the rotation angle of the first housing 2 is different from that of the second housing 3. For example, the resistance of the resistance mechanism 16A, i.e., resistance to the rotation of the first portion 17 connected to the first housing 2 with respect to the third portion 19, can be set larger than the resistance of the resistance mechanism 16B, i.e., resistance to the rotation of the second portion 18 connected to the second housing 3 with respect to the third portion 19. This makes the first portion 17 less movable and the second portion 18 more movable with respect to the third portion 19. Accordingly, when the first housing 2 and the second housing 3 are moved to the open position and the electronic device 1 is opened from the closed state as illustrated in FIG. 5, the hinge mechanism 5 is in the state as illustrated in FIG. 12, and the electronic device 1 is in the state as illustrated in FIG. 13, i.e., in the state where the second housing 3 is largely open. As illustrated in FIG. 13, in this case, the electronic device 1 is placed on the plane P (placement surface) such that the surface 2h of the first housing 2 and plane part of the outer surface 4h of the connection portion 4 are continuous. Thus, the electronic device 1 can be securely placed on the plane P. The outer surface 4h is an example of a contact surface (contact portion). Incidentally, the resistance mechanism 16 (16A and 16B) need not necessarily be provided correspondingly to both the two hinge mechanisms 5, and may be provided correspondingly to either one of them.

With the structure as described in the embodiment in which the first housing 2 and the second housing 3 are rotatably connected via the hinge mechanisms 5 and the connection portion 4, there are two rotation axes, i.e., the first rotation axis Ax1 and the second rotation axis Ax2. As a result, in the closed state as illustrated in FIG. 5, the surface 2a of the first housing 2 and the surface 3a of the second housing 3 facing each other may be misaligned or displaced along a direction crossing the first rotation axis Ax1 and the second rotation axis Ax2, i.e., a direction crossing a direction in which the edges 2b and 3b (sides) extend (in the embodiment, for example, a direction perpendicular to the first rotation axis Ax1 and the second rotation axis Ax2, the horizontal direction in FIG. 5). If such displacement occurs, the electronic device 1 in the closed state may appear twisted. Further, if the surfaces 2a and 3a are displaced while in contact with each other, a scratch or the like may be made on the surfaces 2a and 3a. In view of this, according to the embodiment, there is provided an engagement mechanism 21 that prevents the displacement of the first housing 2 and the second housing 3 in a direction crossing the first rotation axis Ax1 and the second rotation axis Ax2.

As illustrated in FIG. 1, the engagement mechanism 21 comprises a protrusion 21a provided to the second housing 3 and a receiving portion 21b provided to the first housing 2 and having a recess 21c that receives the protrusion 21a. The protrusion 21a is an example of a second engagement portion, while the receiving portion 21b is an example of a first engagement portion. In the embodiment, the receiving portion 21b and the protrusion 21a that constitute the engagement mechanism 21 are provided to end portions (both ends) of the edge 2c of the first housing 2 and the edge 3c of the second housing 3 on the distal side, respectively. The protrusion 21a and the receiving portion 21b engage with each other in a direction crossing the first rotation axis Ax1 and the second rotation axis Ax2. In the embodiment, the engagement between the protrusion 21a and the receiving portion 21b allows the surface 2a of the first housing 2 and the surface 3a of the second housing 3 to face each other with a space therebetween. In other words, for example, if the height of the protrusion 21a (distance from the surface 3a to the top of the protrusion 21a) is larger than the depth of the receiving portion 21b (distance from the surface 2a to the bottom of the receiving portion 21b), the surfaces 2a and 3a are prevented from coming in contact with each other when the first housing 2 and the second housing 3 are brought close to each other. The space between the surface 2a of the first housing 2 and the surface 3a of the second housing 3 may be provided by the convexo-concave structure or the like of another portion.

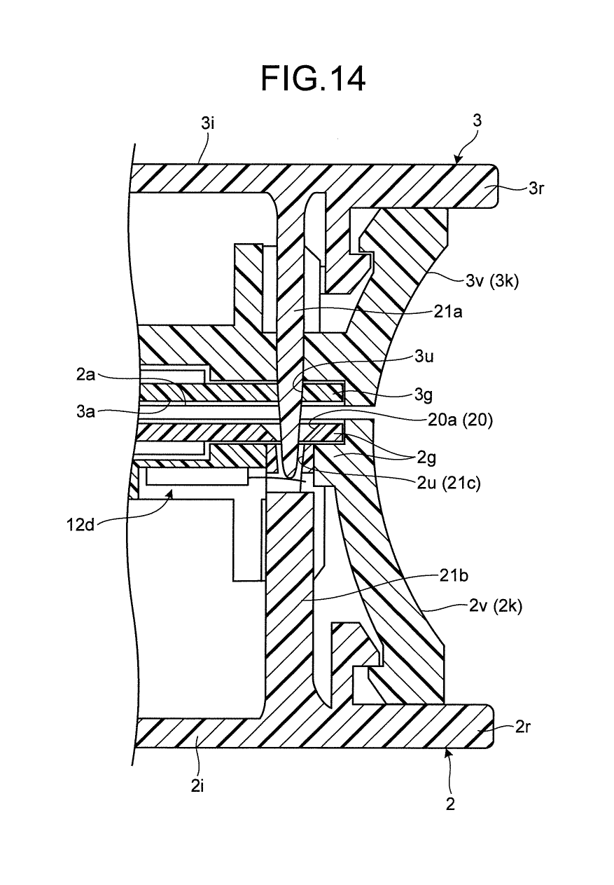

In the embodiment, there is provided a guide mechanism 22 that guides at least one of the protrusion 21a and the receiving portion 21b to its engagement position before the protrusion 21a and the receiving portion 21b engage with each other. In the embodiment, for example, the guide mechanism 22 is provided to the surface 2a of the first housing 2 as a groove 22a extending along a direction crossing the first rotation axis Ax1 and the second rotation axis Ax2 (in the embodiment, for example, a direction perpendicular to the first rotation axis Ax1 and the second rotation axis Ax2, the horizontal direction in FIG. 14). The groove 22a becomes deeper toward the recess 21c. Accordingly, when the first housing 2 and the second housing 3 are brought close to each other, the protrusion 21a fits in the groove 22a and is guided along the groove 22a to the position of the recess 21c (the receiving portion 21b) as the engagement position. The guide mechanism 22 is not limited to this example and may be, for another example, formed as an inclined surface (not illustrated) on the top of the protrusion 21a. In this case, the inclined surface comes in contact with an edge of the receiving portion 21b and is guided to the engagement position where the protrusion 21a engages with the recess 21c (the receiving portion 21b).

In the embodiment, as illustrated in FIG. 14, the protrusion 21a is provided to the back wall 3i of the second housing 3. The protrusion 21a extends toward the front wall 3g, passes through the opening 3u provided as a through hole or a notch to the front wall 3g, and protrudes on the surface 3a. On the other hand, the receiving portion 21b is provided to the back wall 2i of the first housing 2. The receiving portion 21b extends toward the front wall 2g, and is exposed from the opening 2u provided as a through hole or a notch to the front wall 2g to the upper side of the surface 2a. That is, the protrusion 21a and the receiving portion 21b are provide to the back walls 3i and 2i as members facing the inside of the housing while protruding or being exposed through the openings 3u and 2u, respectively. Accordingly, the protrusion 21a and the receiving portion 21b are supported at at least two points in the thickness direction of the first housing 2 or the second housing 3 (the vertical direction in FIG. 14). Thus, compared to the case where the protrusion 21a and the receiving portion 21b are supported at one point, stress on the protrusion 21a and the receiving portion 21b can be reduced. Incidentally, the back walls 3i and 2i are an example of members facing the inside of the housing. The front walls 2g and 3g are an example of walls having the openings 3u and 2u, respectively. The protrusion 21a and the receiving portion 21b need not necessarily be provided to the back walls 3i and 2i and, for example, may be provided as being screwed to circuit boards housed in the first housing 2 and the second housing 3, respectively. A ring-like cap (interposer) as an elastic member made of rubber, sponge, resin, or the like may be fitted in each of the openings 3u and 2u to be interposed between the protrusion 21a or the receiving portion 21b and the edge of the opening 3u or 2u.

The protrusion 21a may be used as an object of open/close detection by the open/close sensor 12d. For example, the open/close sensor 12d may be a contact sensor (a pressure sensor, etc.) such that it can detect the open/close of the first housing 2 and the second housing 3 by a contact with the protrusion 21a.

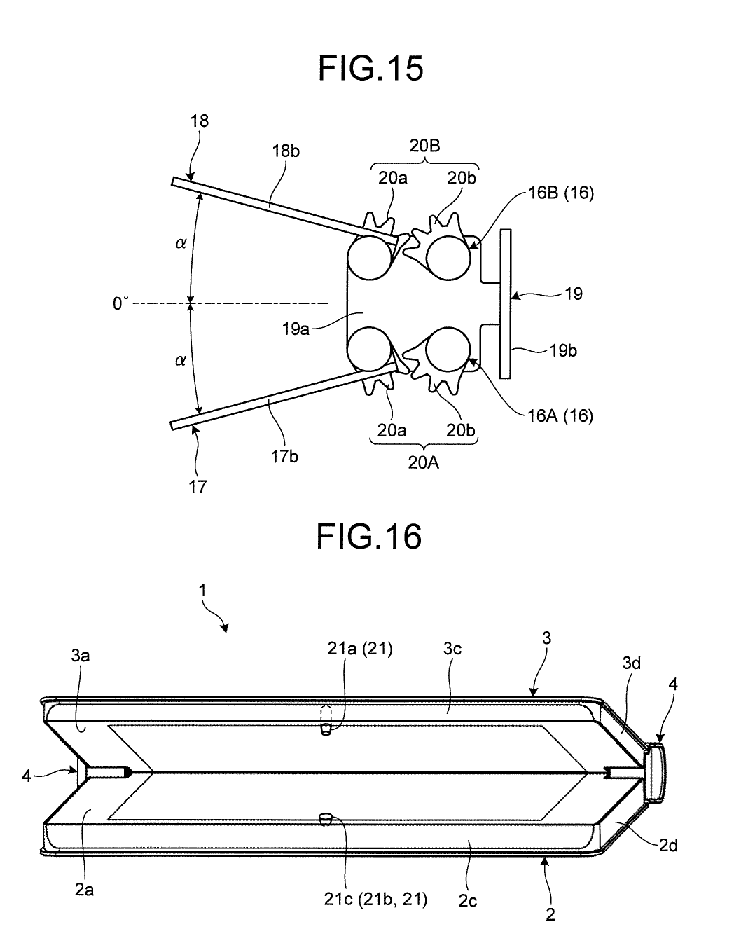

If the resistance of the resistance mechanism 16 is large, which hinders the relative movement of the first housing 2 and the second housing 3, this may prevent the guide mechanism 22 from working. That is, the guide mechanism 22 guides at least one of the protrusion 21a and the receiving portion 21b in a direction crossing the first rotation axis Ax1 and the second rotation axis Ax2. For this reason, it is preferable that the first housing 2 and the second housing 3 relatively move easily in the direction crossing the first rotation axis Ax1 and the second rotation axis Ax2. In view of this, the resistance mechanism 16 of the embodiment is set such that its resistance when the angle between the first housing 2 and the second housing 3 is small, i.e., the surface 2a of the first housing 2 and the surface 3a of the second housing 3 (both the display screens 6a) are close to each other (in a predetermined angle range), is smaller than that when the angle between the first housing 2 and the second housing 3 is large, i.e., when the display screens 6a on the first housing 2 and the second housing 3 are separated from each other. More specifically, as illustrated in FIG. 15, when the first housing 2 and the second housing 3 are at a small angle (assuming that the angle in the closed position is 0°, in the range of 0° to α°), the gears 20a and 20b do not mesh with each other because their teeth do not face each other, and thereby the resistance of the resistance mechanism 16 (16A and 16B) does not act between the first housing 2 and the connection portion 4 as well as between the second housing 3 and the connection portion 4. The transmission mechanisms 20A and 20B are an example of a switch mechanism (change mechanism) that switches (changes) between meshing state and non-meshing state, switches the resistance of the resistance mechanism 16 between acting state and non-acting state, or changes the resistance of the resistance mechanism 16 according to the rotation angle. Incidentally, the gears 20b may have teeth over the circumference.

When the user wants to use the electronic device 1 in either one of the placed modes (for example, the mode (1) described above) for some reason, if the protrusion 21a is located on the placed part (for example, the first housing 2) placed on the plane P (placement surface), the protrusion 21a is likely to interfere with his/her fingers. Therefore, preferably, the protrusion 21a is provided to the raised part (for example, the second housing 3), and the receiving portion 21b is provided to the placed part (for example, the first housing 2). In this case, the controller 12a as a display controller displays an image (not illustrated) representing a text input module (for example, an image of a keyboard, a frame surrounding letters, elements corresponding to letters, etc.) on the display screen 6a of the placed part (for example, the first housing 2). Besides, differentiation of resistance between the resistance mechanisms 16A and 16B facilitates to define the placed part and the raised part. That is, as described above, for example, by setting the resistance of the resistance mechanism 16A to be larger than the resistance of the resistance mechanism 16B, it is easier to achieve the state of the hinge mechanism 5 illustrated in FIG. 12 and the state of the electronic device 1 illustrated in FIG. 13, i.e., the state where the first housing 2 is the placed part and the second housing 3 is the raised part. Thus, the protrusion 21a is less likely to interfere with user's fingers.

As illustrated in FIG. 14, in the embodiment, the circumferential wall 2k (side wall) on the edge 2c side and the circumferential wall 3k (side wall) on the edge 3c side comprise curved portions 2v and 3v (recesses), respectively. The curved portions 2v and 3v are recessed toward the inside of the first housing 2 and the second housing 3. A combination of the curved portions 2v and 3v forms a curbed surface (side surface) having the bottom corresponding to the facing surfaces 2a and 3a. This makes it easier for the user to put his/her fingers on the circumferential walls 2k and 3k (side walls) on the side of the edges 2c and 3c upon opening the first housing 2 and the second housing 3.

As described above, according to the embodiment, the electronic device 1 comprises the resistance mechanism 16 (16A and 16B) that applies different resistance to the rotation of the first housing 2 and the connection portion 4 and to the rotation of the second housing 3 and the connection portion 4. This makes one of the first housing 2 and the second housing 3 (for example, the second housing 3) that is subjected to smaller resistance from the resistance mechanism 16 (for example, the resistance mechanism 163) more movable, and the other (for example, the first housing 2) that is subjected to larger resistance from the resistance mechanism 16 (for example, the resistance mechanism 16A) less movable. Accordingly, the more movable housing can be moved largely first from the closed position and thereby suitably used as the raised part, while the less movable housing can be suitably used as the placed part. Note that this is by way of example only. The resistance (torque) of the resistance mechanism 16 can be variously set depending on various use modes. Thus, for example, a predetermined orientation of the first housing 2 and the second housing 3 can be easily achieved.

According to the embodiment, the connection portion 4 extends in a direction away from the edge 2b of the first housing 2 and the edge 3b of the second housing 3. Thus, the connection portion 4 can be used as a base of the electronic device 1.

According to the embodiment, the connection portion 4 also extends along the edge 2b of the first housing 2 and the edge 3b of the second housing 3. Thus, the connection portion 4 can be used as a handle, a housing (equipment) for components such as a battery, a portion where the connector 14 and the operation module 15 are provided, and the like.

According to the embodiment, the connection portion 4 is connected to the edge 2b of the first housing 2 as well as the edge 3b of the second housing 3. With this, even if the first housing 2 and the second housing 3 become thinner as the display panels 6 become thinner, a portion can be ensured on the outer surface 4h that has a length nearly corresponding to the total thickness of the first housing 2 and the second housing 3. Thus, a housing (equipment) for components, the connector 14, the operation module 15, and the like can be easily provided to the connection portion 4. As in the embodiment, if the connection portion 4 extends in a direction away from the edge 2b of the first housing 2 and the edge 3b of the second housing 3, or if the connection portion 4 extends along the edge 2b of the first housing 2 and the edge 3b of the second housing 3, this also facilitates to provide a housing (equipment) for components, the connector 14, the operation module 15, and the like to the connection portion 4.

According to the embodiment, the connection portion 4 comprises the outer surface 4h as a contact portion that is in contact with the plane P (placement surface) in the first placed modes. The connection portion 4 further comprises the contact portions 4f and 4g each in contact with the plane P (placement surface) in corresponding one of the third placed modes. With this, compared to the case of without the connection portion 4, the electronic device 1 can be securely placed. Further, as illustrated in FIG. 13, the contact portion of the outer surface 4h is a plane. Thus, the electronic device 1 can be more securely placed.

The above embodiment is susceptible to several modifications and variations. For example, while the engagement mechanism 21 is described above as being provided to the both ends of the edges 2c and 3c, it is not so limited. FIG. 16 illustrates a modification of the embodiment. As illustrated in FIG. 16, the engagement mechanism 21 may be located in the center of the edges 2c and 3c. Although not illustrated, the engagement mechanism 21 may be located any other part of the surfaces 2a and 3a.

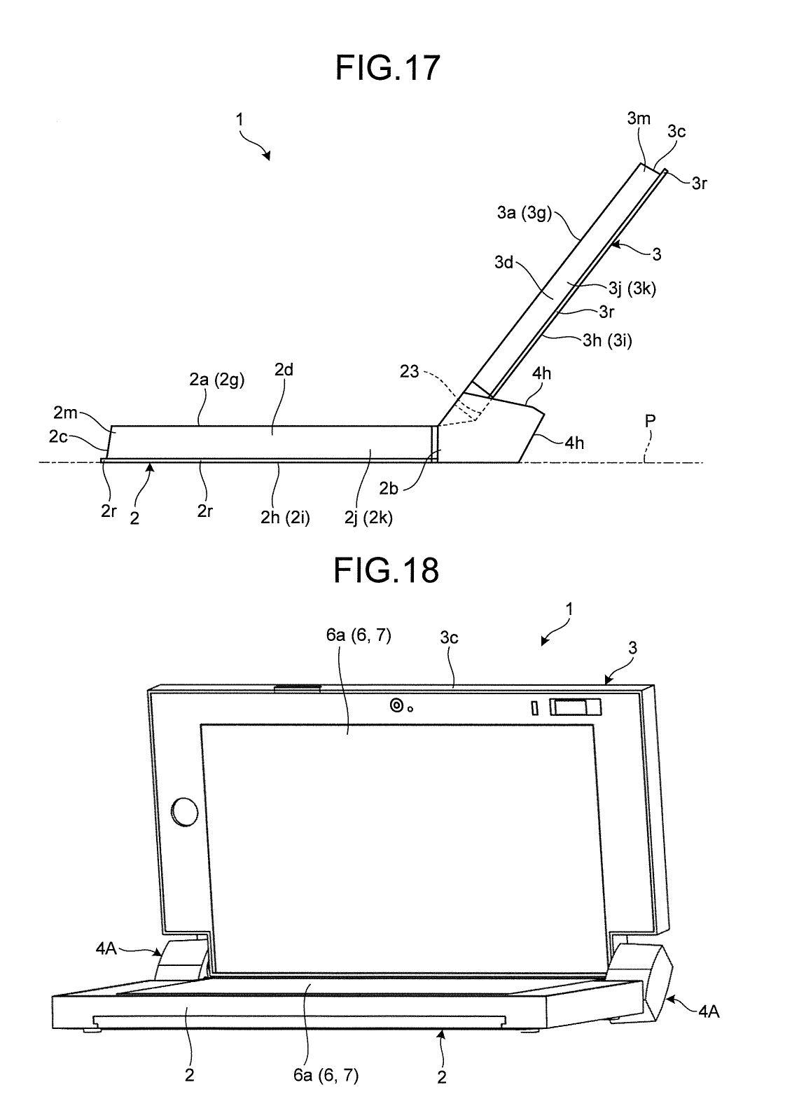

FIG. 17 illustrates another modification of the embodiment. As illustrated in FIG. 17, if there is provided between the edge 2b (or the edge 3b) and the connection portion 4 a clearance 23 to reduce interference between them and allow the second housing 3 to further move in a direction away from the first housing 2, it is possible to increase the tilt angle of the raised part (for example, the second housing 3), i.e., open angle between the first housing 2 and the second housing 3, angle made by the display screens 6a, (specifically, for example, to an angle exceeding 90°), in the placed modes. Besides, the connector 14 and the operation module 15 (see FIG. 8) may be provided to a plurality of plane parts of the outer surface 4h. The connector 14 and the operation module 15 may also be provided to a curved part of the outer surface 4h.

FIG. 18 illustrates still another modification of the embodiment. As illustrated in FIG. 18, the electronic device 1 may comprise separate (two) connection portions 4A on both sides. In this case, the hinge mechanism 5 is housed in each of the connection portions 4A.

The above embodiment may be applied to electronic devices comprising two housings connected to be rotatable about three or more parallel rotation axes.

Further, the above embodiment may be applied to other electronic devices such as a mobile phone, a smartphone, a smartbook, an electronic book terminal, a personal digital assistant (PDA), a game machine, and the like. The above embodiment may also be applied to electronic devices comprising first and second housings only one of which is provided with a display screen. Besides, regarding the electronic device, the first housing, the second housing, the connection portion, the first edge, the second edge, the display screen, the surface, the contact portion, the resistance mechanism, the clearance, the connector, the operation module, and the like, the specifications (number, form, structure, location, arrangement, shape, size, thickness, motion range, material, connection object, etc.) can be suitably modified.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device comprising:
a first housing comprising a first edge and a first display screen;
a second housing comprising a second edge extending along the first edge and a second display screen capable of facing the first display screen;
a connection portion comprising a contact portion that is in contact with a plane when either the first housing or the second housing is placed on the plane and either the second housing or the first housing is raised, the connection portion configured to be connected to the first edge to be rotatable about a first rotation axis and connected to the second edge to be rotatable about a second rotation axis parallel to the first rotation axis; and
a resistance mechanism configured to apply different resistance to rotation of the first housing and the connection portion and to rotation of the second housing and the connection portion.

2. The electronic device of claim 1, wherein, when the first housing is placed on the plane and the second housing is raised, resistance to rotation of the first housing with respect to the connection portion is larger than resistance to rotation of the second housing with respect to the connection portion.

3. The electronic device of claim 1, wherein the connection portion extends in a direction away from the first edge and the second edge.

4. The electronic device of claim 2, wherein the first display screen is configured to display a text input image,
the electronic device further comprising a touch panel on the first display screen, the touch panel configured to receive external input to the text input image.

5. The electronic device of claim 1, wherein the connection portion extends along the first edge and the second edge.

6. The electronic device of claim 5, wherein the connection portion is configured to hold a battery.

7. The electronic device of claim 1, wherein the contact portion is a plane part of an outer surface of the connection portion.

8. The electronic device of claim 7, when the first housing is placed on the plane, the contact portion is continuous with a surface of the first housing facing the plane.

9. The electronic device of claim 8, wherein the connection portion comprises a clearance to allow the second housing to move in a direction away from the first housing when the first housing is placed on the plane and the second housing is raised

10. The electronic device of claim 1, further comprising an operation module or a connector that is exposed when the contact portion is in contact with the plane.
